(19) United States
(12) Patent Application Publication
(10) Pub. No.: US 2025/0176391 A1
(43) Pub. Date: May 29, 2025

(54) PIXEL ARRANGEMENT STRUCTURE, DISPLAY PANEL AND DISPLAY DEVICE

(71) Applicants: KUNSHAN GO-VISIONOX OPTO-ELECTRONICS CO., LTD., Kunshan (CN); HEFEI VISIONOX TECHNOLOGY CO., LTD., Hefei (CN)

(72) Inventors: Mingxing LIU, Kunshan (CN); Bing HAN, Kunshan (CN); Zhe LI, Kunshan (CN); Shizhen FENG, Kunshan (CN); Jingjing ZHAO, Kunshan (CN); Dan ZHANG, Kunshan (CN)

(73) Assignees: KUNSHAN GO-VISIONOX OPTO-ELECTRONICS CO., LTD., Kunshan (CN); HEFEI VISIONOX TECHNOLOGY CO., LTD., Hefei (CN)

(21) Appl. No.: 18/629,192

(22) Filed: Apr. 8, 2024

(30) Foreign Application Priority Data
Nov. 29, 2023 (CN) 202311616249.0

(51) Int. Cl. H10K 59/35

(52) U.S. Cl. CPC H10K 59/353; H10K 59/351; H10K 59/352

(57) ABSTRACT

A pixel arrangement structure, display panel, and display device. The pixel arrangement structure includes a plurality of repeating units each including a first sub-pixel group and a second sub-pixel group. The first sub-pixel group includes a first sub-pixel and a second sub-pixel, and a light-emitting region of the first sub-pixel partially surrounds a light-emitting region of the second sub-pixel. The second sub-pixel group includes a third sub-pixel and a fourth sub-pixel, and a light-emitting region of the third sub-pixel partially surrounds a light-emitting region of the fourth sub-pixel. Adjacent second sub-pixel and fourth sub-pixel are spaced apart by the first sub-pixel or the third sub-pixel. The second sub-pixel and the fourth sub-pixel have the same light-emitting color, which is different from the light-emitting colors of the first sub-pixel and the third sub-pixel.

### CROSS REFERENCE TO RELATED APPLICATION

The present application claims priority to Chinese patent application No. 202311616249.0, titled “Pixel Arrangement Structure, Display Panel and Display Device”, and filed on Nov. 29, 2023, the content of which is hereby incorporated by reference in its entirety.

### TECHNICAL FIELD

The present disclosure relates to the field of display technology, particularly to a pixel arrangement structure, a display panel and a display device.

### BACKGROUND

The Organic Light-Emitting Diode (OLED) display panel is one of the hotspots in today's display panel research field. The OLED display panel has the advantages of low energy consumption, low cost, self-luminous, wide viewing angle and fast response speed. In the related technology, if the aperture ratio is low, the actual light-emitting area may be restricted, the pixel resolution may be difficult to improve, and the light-emitting brightness may also be affected. Therefore, increasing the aperture ratio is one of the future development trends of OLED display panels.

### SUMMARY

Therefore, it is necessary to provide a pixel arrangement structure, a display panel, and a display device to address the problem of how to increase the aperture ratio of an OLED display panel.

According to the first aspect of the present disclosure, a pixel arrangement structure is provided. The pixel arrangement structure includes a plurality of repeating units, each repeating unit includes: a first sub-pixel and a second sub-pixel, and a light-emitting region of the first sub-pixel partially surrounding a light-emitting region of the second sub-pixel; and a second sub-pixel group including a third sub-pixel and a fourth sub-pixel, and a light-emitting region of the third sub-pixel partially surrounds a light-emitting region of the fourth sub-pixel. A light-emitting color of the second sub-pixel is the same as a light-emitting color of the fourth sub-pixel, and is different from a light-emitting color of the first sub-pixel and a light-emitting color of the third sub-pixel. The second sub-pixel and the fourth sub-pixel which are adjacent to each other are spaced apart by the first sub-pixel or the third sub-pixel.

According to the second aspect of the present disclosure, a display panel is provided, which includes: a substrate, the pixel arrangement structure of the above first aspect, the plurality of the sub-pixels provided on the substrate; and an isolation structure provided on the substrate and disposed to space apart adjacent repeating units and space apart every two adjacent sub-pixels of the first sub-pixel, the second sub-pixel, the third sub-pixel and the fourth sub-pixel in the same repeating unit.

According to the fourth aspect of the present disclosure, a display panel is provided, including: a substrate, the pixel arrangement structure of the above third aspect, the plurality of the sub-pixels provided on the substrate; and an isolation structure is provided on the substrate and disposed to space apart adjacent sub-pixels.

According to the technical solution of the present disclosure, one of the sub-pixels partially surrounds another sub-pixel. For example, in the same repeating unit, the light-emitting region of the first sub-pixel of the first sub-pixel group partially surrounds the light-emitting region of the second sub-pixel of the first sub-pixel group, the light-emitting region of the third sub-pixel of the second sub-pixel group partially surrounds the light-emitting region of the fourth sub-pixel of the second sub-pixel group, and the second sub-pixel and the fourth sub-pixel which are adjacent to each other are spaced apart by the first sub-pixel or the third sub-pixel. Firstly, the adjacent first sub-pixel and second sub-pixel have a good color mixing effect, and the adjacent third sub-pixel and fourth sub-pixel have a good color mixing effect, thereby improving the display effect of the display panel. Secondly, the second sub-pixel and the fourth sub-pixel have the same light-emitting color which is different from the light-emitting colors of the first sub-pixel and the third sub-pixel. Combining the fact that the adjacent second sub-pixel and the fourth sub-pixel are spaced apart by the first sub-pixel or the third sub-pixel, it can be understood that in the same repeating unit, there exist a first sub-pixel, a second sub-pixel, and a third sub-pixel which are adjacently arranged, or there exist a first sub-pixel, a fourth sub-pixel and a third sub-pixel which are adjacently arranged. The adjacent first sub-pixel and the second sub-pixel, and the adjacent third sub-pixel and the fourth sub-pixel are compactly arranged, such that by unitizing the pixel arrangement structure, it increases the aperture ratio of the display panel including the pixel arrangement structure, and also improves the display effect of the display panel. For another example, the first sub-pixel and the third sub-pixel adjacent to the second sub-pixel in the first direction each have a portion arranged around the second sub-pixel, resulting in a good color mixing effect of the adjacent first sub-pixel and second sub-pixel, and a good color mixing effect of the adjacent second sub-pixel and third sub-pixel, which is conducive to improving the display effect of the display panel. Since the adjacent first sub-pixel and the third sub-pixel are spaced apart by a second sub-pixel, and the first sub-pixel, the second sub-pixel, and the third sub-pixel have different light-emitting colors, the pixel unit including the first sub-pixel, the second sub-pixel and the third sub-pixel has a good color mixing effect, and the first sub-pixel, the second sub-pixel, and the third sub-pixel in the pixel unit are compactly arranged. As such, by unitizing the pixel arrangement structure, it increases the aperture ratio of the display panel including the pixel arrangement structure, and also improves the display effect of the display panel.

### BRIEF DESCRIPTION OF THE DRAWINGS

FIG. 1 is a partial top view of repeating units and an isolation structure according to an embodiment I of the present disclosure.

FIG. 2 is a partially enlarged schematic view of FIG. 1.

FIG. 3 is a partial top view of repeating units and an isolation structure according to an embodiment II of the present disclosure.

FIG. 4 is a partially enlarged schematic view of FIG. 3.

FIG. 5 is a partial top view of repeating units and an isolation structure according to an embodiment III of the present disclosure.

FIG. 6 is a partially enlarged schematic view of FIG. 5.

FIG. 7 is a partial top view of repeating units and an isolation structure according to an embodiment IV of the present disclosure.

FIG. 8 a partially enlarged schematic view of FIG. 7.

FIG. 9 is a partial top view of repeating units and an isolation structure according to an embodiment V of the present disclosure.

FIG. 10 is a partial sectional view of a display panel according to an embodiment of the present disclosure.

FIG. 11 is a partial top view of repeating units and an isolation structure according to an embodiment VI of the present disclosure.

FIG. 12 is a partial top view of repeating units and an isolation structure according to an embodiment VII of the present disclosure.

FIG. 13 is a schematic structure view of a display device according to an embodiment of the present disclosure.

### DETAILED DESCRIPTION OF THE EMBODIMENTS

In the process of making sub-pixels of a display panel, organic light-emitting materials are usually vaporized onto a substrate through multiple openings of a fine metal mask (FMM). In order to ensure the yield of the product, most manufacturers set the size of the openings of the fine metal mask to be greater than the size of the pixel openings, and make the spacing between the openings of the fine metal mask equal, so that the spacing between adjacent sub-pixels keeps constant, which disadvantageously results in limitation to the improvement of the aperture ratio of the OLED display panel.

In the related technology, an isolation structure is formed on the substrate for spacing apart adjacent sub-pixels, so that in the process of forming sub-pixels by the vapor deposition, the need for the expensive fine metal mask (FMM) can be eliminated, and the production cost of the OLED display panel can be reduced.

The isolation structure in the related technology allows the design of sub-pixels not to be limited by the fine metal mask (FMM). Based on this, in order to increase the aperture ratio of an OLED display panel, the present disclosure provides a pixel arrangement structure, a display panel, and a display device, which increase the aperture ratio of the display panel and also improve the display effect of the display panel.

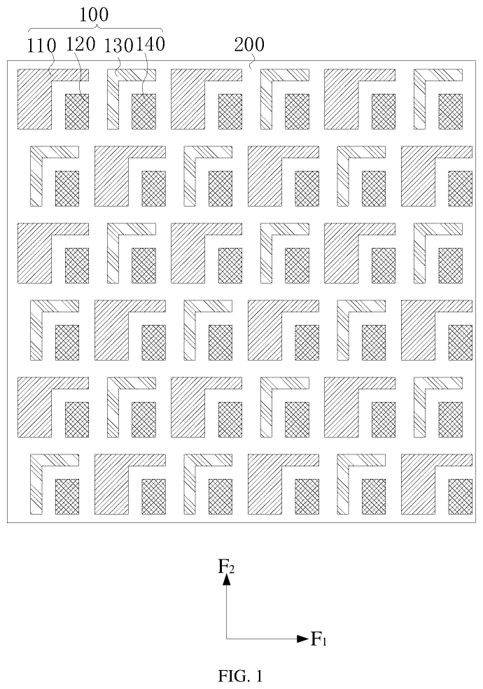

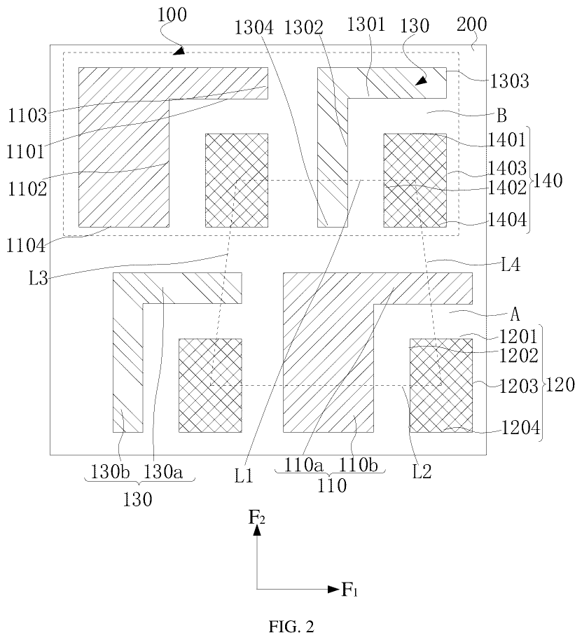

FIG. 1 is a schematic structure view of a pixel arrangement structure in an embodiment of the present disclosure, and FIG. 2 is a partially enlarged schematic view of FIG. 1.

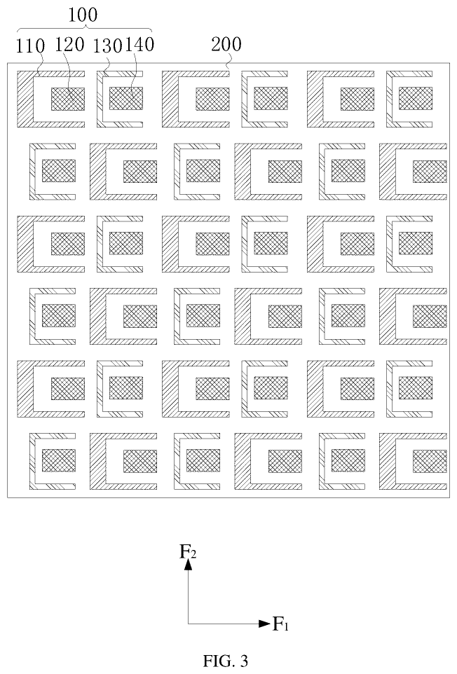

According to the first aspect of the present disclosure, a pixel arrangement structure is provided. Referring to FIGS. 1-2, and in combination with FIGS. 3-8, the pixel arrangement structure provided in an embodiment of the present disclosure includes a plurality of repeating units 100, each of which includes a first sub-pixel group and a second sub-pixel group that are adjacent to each other. The first sub-pixel group includes a first sub-pixel 110 and a second sub-pixel 120. A light-emitting region of the first sub-pixel 110 partially surrounds a light-emitting region of the second sub-pixel 120. The second sub-pixel group includes a third sub-pixel 130 and a fourth sub-pixel 140. A light-emitting region of the third sub-pixel 130 partially surrounds a light-emitting region of the fourth sub-pixel 140.

The light-emitting color of the second sub-pixel 120 is the same as the light-emitting color of the fourth sub-pixel 140, and is different from the light-emitting colors of the first sub-pixel 110 and the third sub-pixel 130, which means that the first sub-pixel 110 and the third sub-pixel 130 each have a different light-emitting color from the second sub-pixel 120. The light-emitting colors of the first sub-pixel 110 and the third sub-pixel 130 may be the same or different.

The specific light-emitting colors of the first sub-pixel 110, the second sub-pixel 120, the third sub-pixel 130, and the fourth sub-pixel 140 can be selected according to the device requirements, sub-pixel area, manufacturing process, etc., and are not specifically limited herein.

Since the first sub-pixel 110 and the third sub-pixel 130 each have a different light-emitting color from the second sub-pixel 120, and the adjacent second sub-pixel 120 and fourth sub-pixel 140 are spaced apart by the first sub-pixel 110 or the third sub-pixel 130, there exist in the same repeating unit 100 one first sub-pixel 110, one second sub-pixel 120 and one third sub-pixel 130 which are adjacently arranged and form a single pixel unit, or there exist one first sub-pixel 110, one fourth sub-pixel 140 and one third sub-pixel 130 which are adjacently arranged and form a single pixel unit. There is a situation where two adjacent pixel units from two adjacent repeating units 100 share the same first sub-pixel 110 or third sub-pixel 130, so that the aperture ratio of the display panel 10 including the pixel arrangement structure can be increased. Moreover, since in the same repeating unit 100, the light-emitting region of the first sub-pixel 110 partially surrounds the light-emitting region of the second sub-pixel 120 and the light-emitting region of the third sub-pixel 130 partially surrounds the light-emitting region of the fourth sub-pixel 140, a pixel unit formed by the first sub-pixel 110, the second sub-pixel 120, and the third sub-pixel 130 which are adjacently arranged has a good color mixing effect, or a pixel unit formed by the first sub-pixel 110, the fourth sub-pixel 140, and the third sub-pixel 130 which are adjacently arranged has a good color mixing effect, which is thus conducive to improving the display effect of the display panel 10. Thus, utilizing the pixel arrangement structure increases the aperture ratio of the display panel 10 and also the display effect of the display panel 10.

In some embodiments, the plurality of repeating units 100 are arranged in an array.

The plurality of repeating units 100 arranged in an array provides a plurality of repeating pixel units. The repeating pixel units each have a good color mixing effect, which is thus conducive to increasing the aperture ratio of the display panel 10, and also conducive to improving the display effect of the display panel 10.

In some embodiments, the plurality of repeating units 100 are arrayed in a first direction F₁ and a second direction F₂ intersecting the first direction F₁. That is, the plurality of repeating units 100 are arranged in rows in the first direction F₁ and in columns in the second direction F₂ intersecting the first direction F₁.

As such, in the first direction F₁, there exist in the same row one first sub-pixel 110, one second sub-pixel 120 and one third sub-pixel 130 which are adjacently arranged in the first direction F₁ and form a single pixel unit, or there exist in the same row one first sub-pixel 110, one fourth sub-pixel 140 and one third sub-pixel 130 which are adjacently arranged in the first direction F₁ and form a single pixel unit, and meanwhile, there exist in the same row two adjacent pixel units sharing the same first sub-pixel 110 or third sub-pixel 130. Considering that the plurality of repeating units 100 are arranged in a column in the second direction F₂, the plurality of repeating pixel units can be provided by utilizing the pixel arrangement structure, and the color mixing effect of each pixel unit is good, which is thus conducive to increasing the aperture ratio of the display panel 10, and also conducive to improving the display effect of the display panel 10.

The first direction F₁ and the second direction F₂ are perpendicular to each other. Exemplarily, one of the first direction F₁ and the second direction F₂ is parallel to the length direction of the display panel 10, and the other of the first direction F₁ and the second direction F₂ is parallel to the width direction of the display panel 10.

In some embodiments, referring to FIGS. 1-4, adjacent repeating units 100 in two adjacent rows are arranged in a staggered manner, i.e., adjacent repeating units 100 in two adjacent rows are arranged in a staggered manner in the first direction F₁. As a result, it can address the issues such as color fringing, stripe patterns, and jagged edges caused by having the same emitting color for all sub-pixels in a column, and it is beneficial for reducing color fringing, stripe patterns, and jagged edges in display images, thereby improving the display effect of the display panel 10.

In some embodiments, the first sub-pixel group and the second sub-pixel group in the repeating unit 100 are adjacently arranged in the first direction F₁.

Specifically, of two repeating units 100 adjacent in the first direction F₁, the first sub-pixel group of one repeating unit 100 is adjacent to the second sub-pixel group of the other repeating unit 100.

It can be understood that the first sub-pixel groups and the second sub-pixel groups are arranged alternately in the first direction F₁. In the first direction F₁, there exist in the same row one first sub-pixel 110, one second sub-pixel 120 and one third sub-pixel 130 which are adjacently arranged in the first direction F₁ and form a single pixel unit, or there exist in the same row one first sub-pixel 110, one fourth sub-pixel 140 and one third sub-pixel 130 which are adjacently arranged in the first direction F₁ and form a single pixel unit, and meanwhile, there exist in the same row two adjacent pixel units sharing the same first sub-pixel 110 or third sub-pixel 130. As a result, the plurality of repeating pixel units can be formed to be arranged in rows in the first direction F₁ by utilizing the pixel arrangement structure, and each pixel unit has a good color mixing effect, which is conducive to increasing the aperture ratio of the display panel 10, and also conducive to improving the display effect of the display panel 10.

In some embodiments, referring to FIGS. 14, of two repeating units 100 adjacent in the first direction F₂, the first sub-pixel group of one repeating unit 100 is adjacent to the second sub-pixel group of the other repeating unit 100.

In other words, the first sub-pixel group of the repeating unit 100 located in the N-th row and the second sub-pixel group of the repeating unit 100 located in (N+1)-th row are arranged in the same column, and the second sub-pixel group of the repeating unit 100 located in the N-th row and the first sub-pixel group of the repeating unit 100 located in the (N+1)-th row are arranged in the same column, where N is greater than zero and is a natural number.

It is to be understood that the first sub-pixel groups and the second sub-pixel groups are arranged alternately in the second direction F₂. As such, firstly, in the first direction F₁, there exist in the same row one first sub-pixel 110, one second sub-pixel 120 and one third sub-pixel 130 which are adjacently arranged in the first direction F₁ and form a single pixel unit, or there exist in the same row one first sub-pixel 110, one fourth sub-pixel 140 and one third sub-pixel 130 which are adjacently arranged in the first direction F₁ and form a single pixel unit, and meanwhile, there exist in the same row two adjacent pixel units sharing the same first sub-pixel 110 or third sub-pixel 130. Secondly, in the second direction F₂, there exist in the same column one first sub-pixel 110, one second sub-pixel 120 and one third sub-pixel 130 which are adjacently arranged in the second direction F₂ and form a single pixel unit, or there exist in the same column one first sub-pixel 110, one fourth sub-pixel 140 and one third sub-pixel 130 which are adjacently arranged in the second direction F₂ and form a single pixel unit, and meanwhile, there exist in the same column two adjacent pixel units sharing the same first sub-pixel 110 or third sub-pixel 130. As a result, the plurality of repeating pixel units can be formed to be arranged in rows in the first direction F₁ and in columns in the second direction F₂ by utilizing the pixel arrangement structure, and the color mixing effect of each pixel unit is good, which is conducive to increasing the aperture ratio of the display panel 10, and also conducive to improving the display effect of the display panel 10.

In some embodiments, referring to FIGS. 1-4, in the first direction F₁, a connecting line connecting the centers of the second sub-pixel 120 and the fourth sub-pixel 140 located in the same row is a straight line.

That is, in the first direction F₁, the connecting line that connects the centers of all second sub-pixels 120 and all fourth sub-pixels 140 located in the same row is a straight line. As such, it is beneficial to the wiring of the second sub-pixels 120 and the fourth sub-pixels 140 in the same row, and also beneficial for the second sub-pixels 120 and the fourth sub-pixels 140 in the same row to be uniformly arranged, which is to a certain extent conducive to fully utilizing the arrangement space of the display panel 10, and thus conducive to increasing the aperture ratio of the display panel 10.

In the specific embodiments shown in FIGS. 1-4, in the second direction F₂, the connecting line connecting the centers of the second sub-pixel 120 and the fourth sub-pixel 140 located in the same column is a broken line. As such, it enables to fully utilize the arrangement space of the display panel 10 while maintaining substantially the same spacing between adjacent sub-pixels, thereby increasing the aperture ratio of the display panel 10.

It can be readily understood that the present disclosure is not limited thereto, and it is also possible that in the second direction F₂, the connecting line connecting the centers of the second sub-pixel 120 and the fourth sub-pixel 140 located in the same column is a straight line. That is, in the second direction F₂, the connecting line connecting the centers of all second sub-pixels 120 and all fourth sub-pixels 140 located in the same column is a straight line.

As such, it is beneficial to the wiring of the second sub-pixels 120 and the fourth sub-pixels 140 in the same column, and also beneficial for the second sub-pixels 120 and the fourth sub-pixels 140 in the same column to be uniformly arranged, which is to a certain extent conducive to fully utilizing the arrangement space of the display panel 10, and thus conducive to increasing the aperture ratio of the display panel 10.

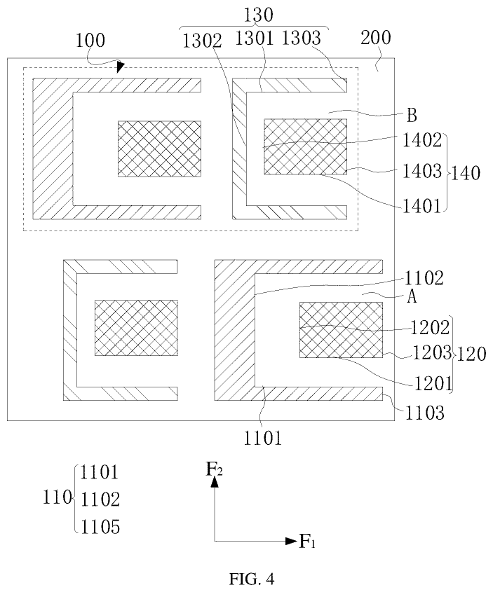

In some embodiments, as shown in FIGS. 3-4, the first sub-pixel 110 is axially symmetrical with respect to a first symmetry line extending in the first direction F₁, and the third sub-pixel 130 is symmetrical with respect to a second symmetry line extending in the first direction F₁. As such, it is conducive to uniformly arranging the first sub-pixels 110 in the same row and uniformly arranging the third sub-pixels 130 in the same row, which is to a certain extent conducive to fully utilizing the arrangement space of the display panel 10, and thus conducive to increasing the aperture ratio of the display panel 10.

In the present embodiment, the first symmetry line of the first sub-pixel 110 and the second symmetry line of the third sub-pixel 130 located in the same row are collinear with each other, and pass through the centers of the second sub-pixel 120 and the fourth sub-pixel 140 located in the same row as the first sub-pixel 110 and second the third sub-pixel 130. As such, it is beneficial for the first sub-pixel 110, the second sub-pixels 120, the third sub-pixel 130 and the fourth sub-pixels 140 located in the same row to be uniformly arranged, which is to a certain extent conducive to fully utilizing the arrangement space of the display panel 10, and thus conducive to increasing the aperture ratio of the display panel 10.

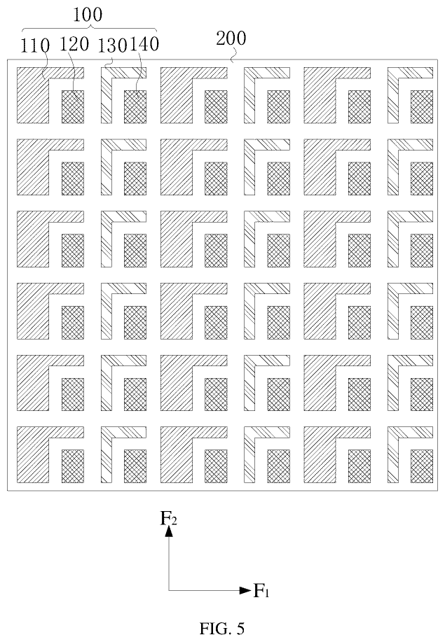

In some other embodiments, as shown in FIGS. 5-8, the plurality of repeating units 100 are arrayed in a first direction F₁ and a second direction F₂ intersecting the first direction F₁. The first sub-pixel groups of two repeating units 100 adjacent in the second direction F₂ are located in the same column, and the second sub-pixel groups of two repeating units 100 adjacent in the second direction F₂ are located in the same column.

That is, the repeating units 100 adjacent to each other in two adjacent rows are located in the same column in the second direction F₂. It facilitates the wiring of the sub-pixels of the repeating units 100 in the same column, and meanwhile, the repeating units 100 can be uniformly arranged, which is to a certain extent conducive to fully utilizing the arrangement space of the display panel 10, and thus conducive to increasing the aperture ratio of the display panel 10.

In this embodiment, the first sub-pixel group and the second sub-pixel group of the repeating unit 100 are adjacently arranged in the first direction F₁. The first sub-pixel groups are arranged in columns in the second direction F₂, and the second sub-pixel groups are arranged in columns in the second direction F₂.

It can be understood that, firstly, the first sub-pixel groups and the second sub-pixel groups are alternately arranged in the first direction F₁. In the first direction F₁, there exist in the same row one first sub-pixel 110, one second sub-pixel 120 and one third sub-pixel 130 which are adjacently arranged in the first direction F₁ and form a single pixel unit, or there exist in the same row one first sub-pixel 110, one fourth sub-pixel 140 and one third sub-pixel 130 which are adjacently arranged in the first direction F₁ and form a single pixel unit, and meanwhile, there exist in the same row two adjacent pixel units sharing the same first sub-pixel 110 or third sub-pixel 130. As a result, the plurality of repeating pixel units can be formed to be arranged in rows in the first direction F₁ by utilizing the pixel arrangement structure, and each pixel unit has a good color mixing effect, which is conducive to increasing the aperture ratio of the display panel 10, and also conducive to improving the display effect of the display panel 10. Secondly, since the first sub-pixel groups are arranged in columns in the second direction F₂ and the second sub-pixel groups are arranged in columns in the second direction F₂, it facilitates the wiring of the first sub-pixel groups in the same column and the wiring of the second sub-pixel groups in the same column.

As shown in FIGS. 5-8, in the first direction F₁, a connecting line connecting the centers of the second sub-pixel 120 and the fourth sub-pixel 140 located in the same row is a straight line. That is, in the first direction F₁, the connecting line that connects the centers of all second sub-pixels 120 and all fourth sub-pixels 140 located in the same row is a straight line. As such, it is beneficial to the wiring of the second sub-pixels 120 and the fourth sub-pixels 140 in the same row, and also beneficial for the second sub-pixels 120 and the fourth sub-pixels 140 in the same row to be uniformly arranged, which is to a certain extent conducive to fully utilizing the arrangement space of the display panel 10, and thus conducive to increasing the aperture ratio of the display panel 10.

As shown in FIGS. 5-8, in the second direction F₂, a connecting line connecting the centers of the second sub-pixel 120 and the fourth sub-pixel 140 located in the same column is a straight line. As such, it is beneficial to the wiring of the second sub-pixels 120 and the fourth sub-pixels 140 in the same column, and also beneficial for the second sub-pixels 120 and the fourth sub-pixels 140 in the same column to be uniformly arranged, which is to a certain extent conducive to fully utilizing the arrangement space of the display panel 10, and thus conducive to increasing the aperture ratio of the display panel 10.

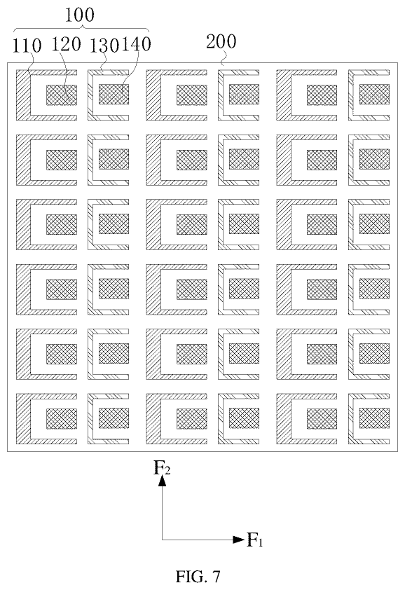

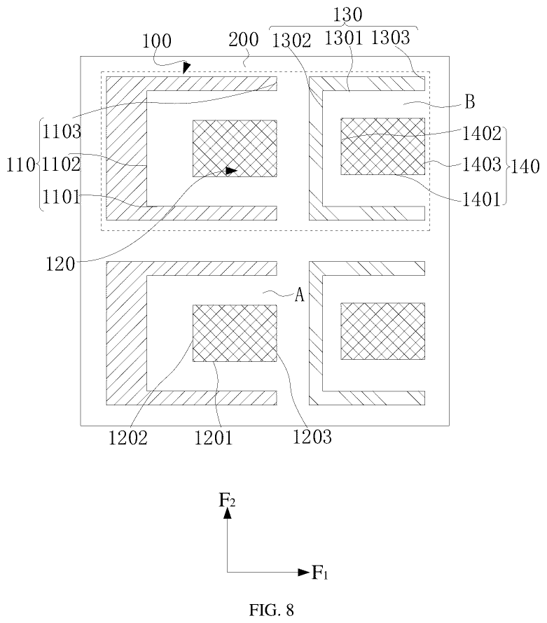

As shown in FIGS. 7-8, the first sub-pixel 110 is symmetrical with respect to a first symmetry line extending in the first direction F₁, and the third sub-pixel 130 is symmetrical with respect to a second symmetry line extending in the first direction F₁. As such, it is conducive to uniformly arranging the first sub-pixels 110 in the same row and uniformly arranging the third sub-pixels 130 in the same row, which is to a certain extent conducive to fully utilizing the arrangement space of the display panel 10, and thus conducive to increasing the aperture ratio of the display panel 10.

In the present embodiment, the first symmetry line of the first sub-pixel 110 and the second symmetry line of the third sub-pixel 130 that are located in the same row are collinear with each other and pass through the centers of the second sub-pixel 120 and the fourth sub-pixel 140 in the same row. As such, it is beneficial for the first sub-pixel 110, the second sub-pixels 120, the third sub-pixel 130 and the fourth sub-pixels 140 located in the same row to be uniformly arranged, which is to a certain extent conducive to fully utilizing the arrangement space of the display panel 10, and thus conducive to increasing the aperture ratio of the display panel 10.

In some embodiments, the light-emitting region of the first sub-pixel 110 includes a first concave portion with an opening facing an adjacent second sub-pixel 120, and the light-emitting region of the second sub-pixel 120 adjacent to the first sub-pixel 110 is at least partially received in a first receiving space A enclosed and formed by the first concave portion.

The light-emitting region of the second sub-pixel 120 is at least partially received in the first receiving space A, which may include that the light-emitting region of the second sub-pixel 120 is entirely received in the first receiving space A (as shown in FIGS. 1-8), or that the light-emitting region of the second sub-pixel 120 is partially received in the first receiving space A. As such, the color mixing effect of the first sub-pixel 110 and the second sub-pixel 120 can be improved. Additionally, it is conducive to fully utilizing the arrangement space of the display panel 10, and thus conducive to increasing the aperture ratio of the display panel 10.

In another embodiment, the light-emitting region of the third sub-pixel 130 includes a second concave portion with an opening facing an adjacent fourth sub-pixel 140, and the light-emitting region of the fourth sub-pixel 140 adjacent to the third sub-pixel 130 is at least partially received in a second receiving space B enclosed and formed by the second concave portion.

The light-emitting region of the fourth sub-pixel 140 is at least partially received in the second receiving space B, which may include that the light-emitting region of the fourth sub-pixel 140 is entirely received in the second receiving space B (as shown in FIGS. 1-8), or that the light-emitting region of the fourth sub-pixel 140 is partially received in the second receiving space B. As such, the color mixing effect of the third sub-pixel 130 and the fourth sub-pixel 140 can be improved. Additionally, it is conducive to fully utilizing the arrangement space of the display panel 10, and thus conducive to increasing the aperture ratio of the display panel 10.

In yet other embodiments, the light-emitting region of the first sub-pixel 110 includes a first concave portion with an opening facing an adjacent second sub-pixel 120, and the light-emitting region of the second sub-pixel 120 adjacent to the first sub-pixel 110 is at least partially received in a first receiving space A enclosed and formed by the first concave portion. Meanwhile, the light-emitting region of the third sub-pixel 130 includes a second concave portion with an opening facing an adjacent fourth sub-pixel 140, and the light-emitting region of the fourth sub-pixel 140 adjacent to the third sub-pixel 130 is at least partially received in a second receiving space B enclosed and formed by the second concave portion.

As shown in FIGS. 2, 4, 6 and 8, the first concave portion includes a first boundary 1101 parallel to the first direction F₁ and a second boundary 1102 parallel to the second direction F₂. The light-emitting region of the second sub-pixel 120 includes a first pixel edge 1201 adjacent to and parallel to the first boundary 1101.

It can be understood that the first sub-pixel 110 and the second sub-pixel 120 are spaced apart from each other and the first pixel edge 1201 is parallel to the first boundary 1101, enabling to maintain a constant spacing between the first pixel edge 1201 and the first boundary 1101, which is conducive to lowering the difficulty of the manufacturing process of the first sub-pixel 110 and the second sub-pixel 120 and fully utilizing the arrangement space of the display panel 10, and thus conducive to increasing the aperture ratio of the display panel 10.

As shown in FIGS. 2, 4, 6 and 8, the light-emitting region of the second sub-pixel 120 includes a second pixel edge 1202 adjacent to and parallel to the second boundary 1102. As such, a constant spacing between the second pixel edge 1202 and the second boundary 1102 is maintained, which is conducive to lowering the difficulty of the manufacturing process of the first sub-pixel 110 and the second sub-pixel 120 and fully utilizing the arrangement space of the display panel 10, and thus conducive to increasing the aperture ratio of the display panel 10.

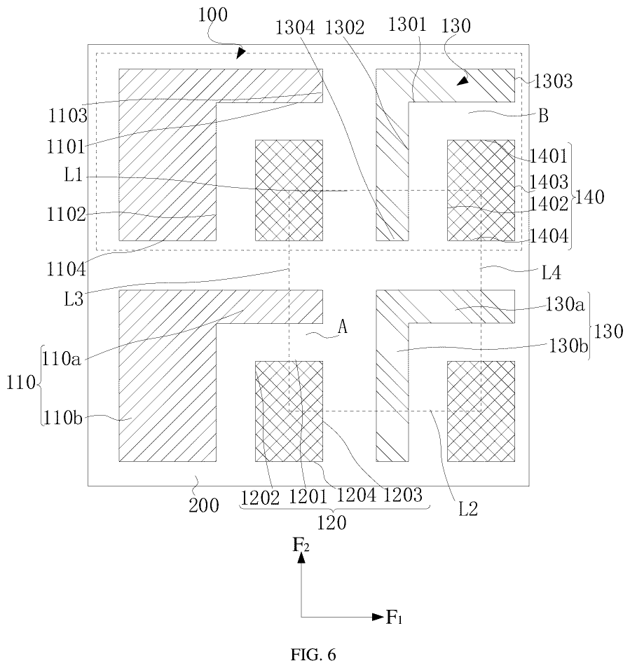

It may be that the first concave portion includes a first boundary 1101 and a second boundary 1102 connected to each other (as shown in FIGS. 2 and 6). As such, the first sub-pixel 110 can be arranged around the adjacent second sub-pixel 120, while facilitating the reduction of the space occupied by the first sub-pixel groups, which enables to fully utilize the arrangement space of the display panel 10, thereby increasing the aperture ratio of the display panel 10.

Alternatively, the first concave portion includes two first boundaries 1101 spaced apart in the second direction F₂, and a second boundary 1102 connected between the two first boundaries 1101 (as shown in FIGS. 4 and 8). The light-emitting region of the second sub-pixel 120 includes two first pixel edges 1201 spaced apart in the second direction F₂, and a second pixel edge 1202 connected between the two first pixel edges 1201. As such, the first sub-pixel 110 is arranged more around the adjacent second sub-pixel 120, which is conducive to improving the color mixing effect of the first sub-pixel 110 and the second sub-pixel 120, thereby improving the display effect of the display panel 10.

As shown in FIGS. 2, 4, 6 and 8, the second concave portion includes a third boundary 1301 parallel to the first direction F₁ and a fourth boundary 1302 parallel to the second direction F₂. The light-emitting region of the fourth sub-pixel 140 includes a third pixel edge 1401 adjacent to and parallel to the third boundary 1301.

It can be understood that the third sub-pixel 130 and the fourth sub-pixel 140 are spaced apart from each other and the third pixel edge 1401 is parallel to the third boundary 1301, enabling to maintain a constant spacing between the third pixel edge 1401 and the third boundary 1301, which is conducive to lowering the difficulty of the manufacturing process of the third sub-pixel 130 and the fourth sub-pixel 140 and fully utilizing the arrangement space of the display panel 10, and thus conducive to increasing the aperture ratio of the display panel 10.

The light-emitting region of the fourth sub-pixel 140 includes a fourth pixel edge 1402 adjacent to and parallel to the fourth boundary 1302. As such, a constant spacing between the fourth pixel edge 1402 and the fourth boundary 1302 is maintained, which is conducive to lowering the difficulty of the manufacturing process of the third sub-pixel 130 and the fourth sub-pixel 140 and fully utilizing the arrangement space of the display panel 10, and thus conducive to increasing the aperture ratio of the display panel 10.

It may be that the second concave portion includes a third boundary 1301 and a fourth boundary 1302 connected to each other (as shown in FIGS. 2 and 6). As such, the third sub-pixel 130 can be arranged around the adjacent fourth sub-pixel 140 while facilitating the reduction of the space occupied by the second sub-pixel groups, which enables to fully utilize the arrangement space of the display panel 10, thereby increasing the aperture ratio of the display panel 10.

It may also be that the second concave portion includes two third boundaries 1301 spaced apart in the second direction F₂, and a fourth boundary 1302 connected between the two third boundaries 1301. The light-emitting region of the fourth sub-pixel 140 includes two third pixel edges 1401 spaced apart in the second direction F₂, and a fourth pixel edge 1402 connected between the two third pixel edges 1401 (as shown in FIGS. 4 and 8).

As such, the third sub-pixel 130 can be arranged more around the adjacent fourth sub-pixel 140, which is conducive to improving the color mixing effect of the third sub-pixel 130 and the fourth sub-pixel 140, and thus conducive to improving the display effect of the display panel 10.

In some embodiments, in the first direction F₁, the adjacent first boundary 1101 and the third boundary 1301 are collinear, and the second boundary 1102 and the fourth boundary 1302 are arranged on the same side of the first boundary 1101 or the third boundary 1301 in the second direction F₂.

As shown in FIGS. 3, 4, 7 and 8, it may be that the first concave portion includes a first groove arranged in the first direction F₁ and in communication with the first receiving space A, and the second concave portion includes a second groove arranged in the first direction F₁ and in communication with the second receiving space B, with the first groove and the second groove facing the same direction.

As shown in FIGS. 1, 2, 5 and 6, it may also be that the first concave portion includes a first groove arranged in the first direction F₁ and in communication with the first receiving space A, and the second concave portion includes a second groove arranged in the first direction F₁ and in communication with the second receiving space B, with the first groove and the second groove facing the same direction. The first concave portion also includes a third groove arranged in the second direction F₂ and in communication with the first receiving space A, and the second concave portion includes a fourth groove arranged in the second direction F₂ and in communication with the second receiving space B, with the third groove and the fourth groove facing the same direction.

It can be understood that the first concave portion and the second concave portion include grooves facing the same direction, so as to facilitate the spacing of adjacent sub-pixels while facilitating the full utilization of the arrangement space of the display panel 10, thereby increasing the aperture ratio of the display panel 10.

In some embodiments, as shown in FIGS. 1-8, the light-emitting region of the second sub-pixel 120 further includes an eighth pixel edge 1203 opposite to and parallel to the second pixel edge 1202, and the light-emitting region of the first sub-pixel 110 includes a ninth pixel edge 1103 parallel to the second direction F₂. The eighth pixel edge 1203 and the ninth pixel edge 1103 in adjacent first sub-pixel 110 and second sub-pixel 120 are collinear.

In the specific embodiments as shown in FIGS. 3, 4, 7 and 8, the second pixel edge 1202 is connected between the two first pixel edges 1201 at one end, and the eighth pixel edge 1203 is connected between the two first pixel edges 1201 at the other end.

It can be understood that in the second direction F₂, the sizes of the first sub-pixel groups in the first direction F₁ are the same, which facilitates the full utilization of the arrangement space of the display panel 10, thereby increasing the aperture ratio of the display panel 10.

In some embodiments, as shown in FIGS. 1-8, the light-emitting region of the fourth sub-pixel 140 further includes a tenth pixel edge 1403 opposite to and parallel to the fourth pixel edge 1402, and the light-emitting region of the third sub-pixel 130 includes an eleventh pixel edge 1303 parallel to the second direction F₂. The tenth pixel edge 1403 and the eleventh pixel edge 1303 in adjacent third sub-pixel 130 and fourth sub-pixel 140 are collinear.

The tenth pixel edge 1403 and the eleventh pixel edge 1303 in the third sub-pixels 130 and fourth sub-pixels 140 in the same column are collinear.

In the specific embodiments shown in FIGS. 3, 4, 7 and 8, the fourth pixel edge 1402 is connected between the two third pixel edges 1401 at one end, and the tenth pixel edge 1403 is connected between the two third pixel edges 1401 at the other end.

It can be understood that in the second direction F₂, the sizes of the second sub-pixel groups in the first direction F₁ are the same, which facilitates the full utilization of the arrangement space of the display panel 10, thereby increasing the aperture ratio of the display panel 10.

In some embodiments, as shown in FIGS. 1-2 and 5-6, the light-emitting region of the second sub-pixel 120 further includes a twelfth pixel edge 1204 opposite to and parallel to the first pixel edge 1201. The light-emitting region of the first sub-pixel 110 includes a thirteenth pixel edge 1104. The twelfth pixel edge 1204 and the thirteenth pixel edge 1104 in the adjacent first sub-pixel 110 and second sub-pixel 120 are collinear.

The twelfth pixel edge 1204 and the thirteenth pixel edge 1104 in the first sub-pixel 110 and the second sub-pixel 120 in the same row are collinear.

It can be understood that in the first direction F₁, the sizes of the first sub-pixel groups in the second direction F₂ are the same, which facilitates the full utilization of the arrangement space of the display panel 10, thereby increasing the aperture ratio of the display panel 10.

In some embodiments, as shown in FIGS. 1-2 and 5-6, the light-emitting region of the fourth sub-pixel 140 further includes a fourteenth pixel edge 1404 opposite to and parallel to the third pixel edge 1401. The light-emitting region of the third sub-pixel 130 includes a fifteenth pixel edge 1304. The fourteenth pixel edges 1404 and the fifteenth pixel edge 1304 in the adjacent third sub-pixel 130 and fourth sub-pixel 140 are collinear.

The fourteenth pixel edge 1404 and the fifteenth pixel edge 1304 in the third sub-pixel 130 and the fourth sub-pixel 140 in the same row are collinear.

It can be understood that in the first direction F₁, the sizes of the second sub-pixel groups in the second direction F₂ are the same, which facilitates the full utilization of the arrangement space of the display panel 10, thereby increasing the aperture ratio of the display panel 10.

In this embodiment, the twelfth pixel edge 1204, the thirteenth pixel edge 1104, the fourteenth pixel edge 1404, and the fifteenth pixel edge 1304 in the first sub-pixel group and the second sub-pixel group in the same row are collinear.

As such, the first sub-pixel group and the second sub-pixel group in the same row are set flush at two sides in the second direction F₂, which facilitates the full utilization of the arrangement space of the display panel 10, thereby increasing the aperture ratio of the display panel 10.

In some embodiments, the area of the light-emitting region of the first sub-pixel 110 is greater than or equal to the area of the light-emitting region of the third sub-pixel 130.

The relationship between the areas of the light-emitting region of the first sub-pixel 110 and the light-emitting region of the third sub-pixel 130 may be determined according to the light-emitting color of the first sub-pixel 110 and the light-emitting color of the third sub-pixel 130, the device requirements and the manufacturing process, etc. The area of the light-emitting region of the first sub-pixel 110 may be set to be greater than the area of the light-emitting region of the third sub-pixel 130, or the area of the light-emitting region of the first sub-pixel 110 may be set to be equal to the area of the light-emitting region of the third sub-pixel 130, which is not specifically limited herein.

In other embodiments, the area of the light-emitting region of the second sub-pixel 120 is equal to the area of the light-emitting region of the fourth sub-pixel 140, and the light-emitting colors of the second sub-pixel 120 and the fourth sub-pixel 140 are the same. Exemplarily, the second sub-pixel 120 and the fourth sub-pixel 140 may each be a sub-pixel of a color sensitive to the human eye, such as a green sub-pixel, which is conducive to improving the resolution of the display panel 10 while making the display of the display panel 10 more uniform.

In yet other embodiments, the area of the light-emitting region of the first sub-pixel 110 is greater than or equal to the area of the light-emitting region of the third sub-pixel 130, and the area of the light-emitting region of the second sub-pixel 120 is equal to the area of the light-emitting region of the fourth sub-pixel 140.

Referring to FIGS. 2, 4, 6 and 8, the area of the light-emitting region of the first sub-pixel 110 is greater than the area of the light-emitting region of the third sub-pixel 130. The light-emitting region of the first sub-pixel 110 includes a first sub-light-emitting region 110a extending in the first direction F₁, and a second sub-light-emitting region 110b extending in the second direction F₂. The light-emitting region of the third sub-pixel 130 includes a third sub-light-emitting region 130a extending in the first direction F₁, and a fourth sub-light-emitting region 130b extending in the second direction F₂. A size of the first sub-light-emitting region 110a in the second direction F₂ is equal to a size of the third sub-light-emitting region 130a in the second direction F₂. A size of the second sub-light-emitting region 110b in the first direction F₁ is greater than a size of the fourth sub-light-emitting region 130b in the first direction F₁.

In the case where the lifespan of the first sub-pixel 110 is low, the lifespan of the second sub-pixel 120 and the fourth sub-pixel 140 is next to high, and the lifespan of the third sub-pixel 130 is high, the size of the second sub-light-emitting region 110b in the first direction F₁ is set to be greater than the size of the fourth sub-light-emitting region 130b in the first direction F₁, and the size of the first sub-light-emitting region 110a in the second direction F₂ is set to be equal to the size of the third sub-light-emitting region 130a in the second direction F₂. As a result, the area of the light-emitting region of the first sub-pixel 110 can be increased to a certain extent, and the area of the light-emitting region of the third sub-pixel 130 can be reduced to a certain extent, so that the overall lifespan of the first sub-pixel 110 and the third sub-pixel 130 can be well balanced and the lifespan of the display panel 10 can be thus improved.

In addition, since the size of the first sub-light-emitting region 110a in the second direction F₂ is equal to the size of the third sub-light-emitting region 130a in the second direction F₂, the sizes of the first sub-pixel 110 and the third sub-pixel 130 in the same row are equal. As such, it facilitates full utilization of the arrangement space of the display panel 10, thereby increasing the aperture ratio of the display panel 10.

In some embodiments, connecting lines that connect centers of two second sub-pixels 120 from four adjacent sub-pixel groups in two adjacent rows and centers of two fourth sub-pixels 140 from the four adjacent sub-pixel groups form a quadrilateral. The quadrilateral includes a first side L1 and a second side L2 opposite to each other in the second direction F₂, and a third side L3 and a fourth side L4 opposite each other in the first direction F₁. At least one of the first side L1 and the second side L2 is parallel to the first direction F₁. That is, it may be that the first side L1 is parallel to the first direction F₁, or it may be that the second side L2 is parallel to the first direction F₁, or it may be that both the first side L1 and the second side L2 are parallel to the first direction F₁.

Exemplarily, as shown in FIGS. 1-8, both the first side L1 and the second side L2 are parallel to the first direction F₁.

It can be understood that the connecting line connecting the centers of the second sub-pixel 120 and the fourth sub-pixel 140 located in the same row is a straight line. As such, it is beneficial to the wiring of the second sub-pixels 120 and the fourth sub-pixels 140 in the same row, and also beneficial for the second sub-pixels 120 and the fourth sub-pixels 140 in the same row to be uniformly arranged, which is to a certain extent conducive to fully utilizing the arrangement space of the display panel 10, and thus conducive to increasing the aperture ratio of the display panel 10.

In some embodiments, it may be that the lengths of the first side L1 and the second side L2 are not equal.

It may also be that the lengths of the third side L3 and the fourth side L4 are equal. It may also be that the lengths of the first side L1 and the second side L2 are not equal, and the lengths of the third side L3 and the fourth side L4 are equal (as shown in FIGS. 1-4).

The quadrilateral is a trapezoid. Specifically, the quadrilateral is an isosceles trapezoid.

As such, two second sub-pixels 120 and two fourth sub-pixels 140 from adjacent four sub-pixel groups in adjacent two rows are uniformly arranged, which is to a certain extent conducive to fully utilizing the arrangement space of the display panel 10, and thus conducive to increasing the aperture ratio of the display panel 10.

In other embodiments, it may be that the length of the first side L1 and the length of the second side L2 are equal. It may also be that the length of the third side L3 and the length of the fourth side L4 are equal. It can be readily understood that it may also be that the length of the first side L1 and the length of the second side L2 are equal, and the length of the third side L3 and the length of the fourth side L4 are equal (as shown in FIGS. 5-9).

As such, two second sub-pixels 120 and two fourth sub-pixels 140 from adjacent four sub-pixel groups in adjacent two rows are uniformly arranged, which enables the plurality of second sub-pixels 120 and the plurality of fourth sub-pixels 140 to be uniformly arranged, which is to a certain extent conducive to fully utilizing the arrangement space of the display panel 10, and thus conducive to increasing the aperture ratio of the display panel 10.

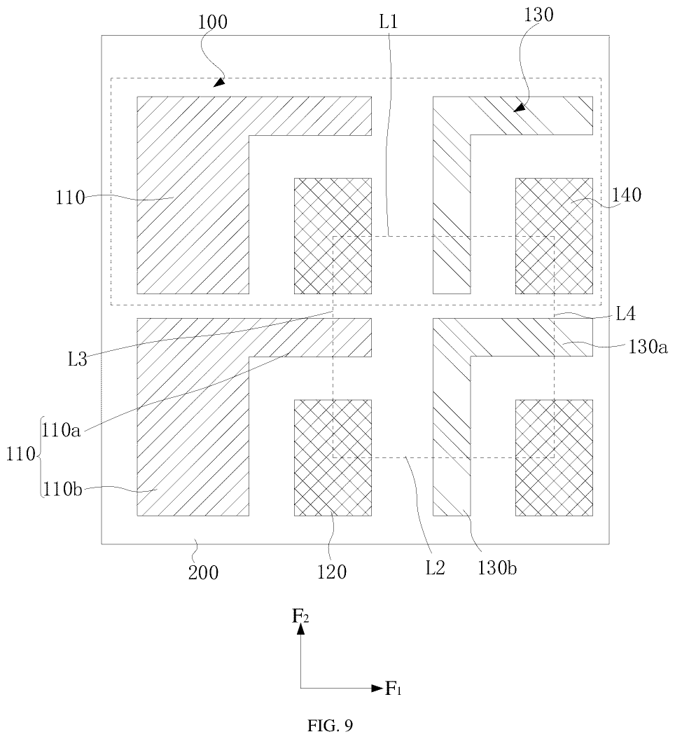

The quadrilateral is a rectangle. In the embodiment shown in FIG. 9, the quadrilateral is specifically a square.

As such, the plurality of second sub-pixels 120 and the plurality of fourth sub-pixels 140 are arranged uniformly, which is to a certain extent conducive to fully utilizing the arrangement space of the display panel 10, and thus conducive to increasing the aperture ratio of the display panel 10. In the case that the second sub-pixel 120 and the fourth sub-pixel 140 are both green sub-pixels, the uniformly arranged plurality of green sub-pixels are further conducive to improving the display effect of the display panel 10.

In some embodiments, the second sub-pixel 120 and the fourth sub-pixel 140 are both green sub-pixels, and the light-emitting color of the first sub-pixel 110 and the light-emitting color of the third sub-pixel 130 are different, so as to better form a pixel unit using the three sub-pixels of different colors, which is more conducive to improving the display effect of the display panel 10.

The first sub-pixel 110 is one of a blue sub-pixel and a red sub-pixel, and the third sub-pixel 130 is the other of the blue sub-pixel and the red sub-pixel.

Specifically, the first sub-pixel 110 is a blue sub-pixel and the third sub-pixel 130 is a red sub-pixel.

The red sub-pixel, the green sub-pixel, and the blue sub-pixel constitute the three primary colors of the color display of the display panel 10, which enables the color display of the display panel 10.

The light-emitting area of the blue sub-pixel is greater than the light-emitting area of the red and green sub-pixels and greater than the light-emitting area of the green sub-pixel.

As such, the overall lifespan of the first sub-pixel 110, the second sub-pixel 120, the third sub-pixel 130, and the fourth sub-pixel 140 can be well balanced, and thus the lifespan of the display panel 10 can be improved.

According to a second aspect of the present disclosure, there is provided a display panel 10 including the pixel arrangement structure of any of the above embodiments.

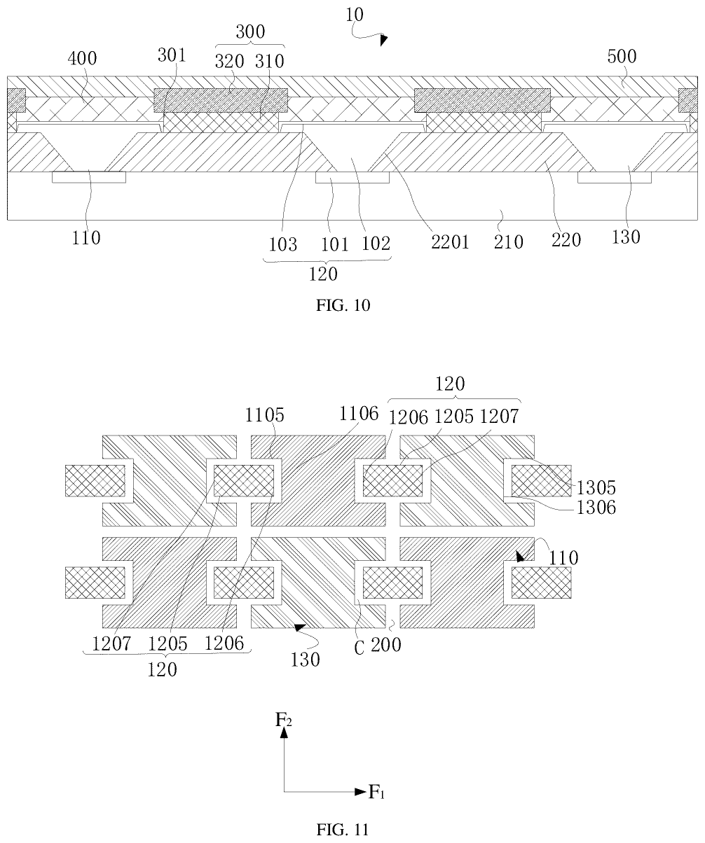

Referring to FIG. 10, the display panel 10 further includes a substrate 210 and an isolation structure 300. The plurality of repeating units 100 and the isolation structure 300 are arranged on the substrate 210 (the fourth sub-pixel 140 is not shown in FIG. 10). The isolation structure 300 is configured to space apart adjacent repeating units 100, and configured to space apart two adjacent ones of the first sub-pixel 110, the second sub-pixel 120, the third sub-pixel 130, and the third sub-pixel 140 in the same repeating unit 100.

The isolation structure 300 is configured to space apart the pixel materials of two adjacent ones of the first sub-pixel 110, the second sub-pixel 120, the third sub-pixel 130, and the fourth sub-pixel 140, so that during the process of forming the plurality of repetitive units 100 by evaporation, the need for expensive fine metal mask (FMM) can be eliminated. As a result, the structural design of the first sub-pixel 110, the second sub-pixel 120, the third sub-pixel 130, and the fourth sub-pixel 140 are no longer limited by the fine metal mask (FMM). Thus, the isolation structure 300, the first sub-pixel 110, the second sub-pixel 120, the third sub-pixel 130, and the fourth sub-pixel 140 may be designed in accordance with the need for increasing the aperture ratio of the display panel 10, which is conducive to increasing the aperture ratio of the display panel 10 while decreasing the cost of production of the display panel 10.

In some embodiments, an outer contour of an orthogonal projection of a top surface of the isolation structure 300 onto the substrate 210 is outside an outer contour of an orthogonal projection of a bottom surface of the isolation structure 300 onto the substrate 210.

Specifically, the isolation structure 300 includes a first isolation portion 310 and a second isolation portion 320 stacked on the substrate 210. An outer contour of an orthogonal projection of the second isolation portion 320 onto the substrate 210 is outside an outer contour of an orthogonal projection of the corresponding first isolation portion 310 onto the substrate 210.

A width of a bottom surface of the second isolation portion 320 is greater than a width of a top surface of the first isolation portion 310. The width refers to a distance between a side of the isolation structure 300 closer to a sub-pixel of one color and a side of the isolation structure 300 closer to a sub-pixel of another color.

As such, the isolation structure 300 isolates the pixel materials of the adjacent sub-pixels in the repeating unit 100 during vaporization. When manufacturing the display panel 10, the isolation structure 300 provides good isolation for the pixel material of the sub-pixels of the repeating unit 100 and the encapsulation material of an encapsulation unit 400, and thus the isolation structure 300 capable of providing complete encapsulation for the sub-pixels of the repeating unit 100 is formed.

In some embodiments, the display panel 10 further includes a pixel fixing layer 220 arranged on the substrate 210.

The pixel fixing layer 220 may be made of polyimide, acrylic, or polyethylene terephthalate, etc. The shape of an orthogonal projection of a pixel opening 2201 onto the substrate 210 may be a rectangle or a trapezoid, etc.

The first sub-pixel 110, the second sub-pixel 120, the third sub-pixel 130, and the fourth sub-pixel 140 each include a first electrode 101, an light-emitting region 102, and a second electrode 103 arranged in a stacked configuration. The pixel fixing layer 220 includes a plurality of pixel openings 2201 each at least partially exposing the first electrode 101. The light-emitting region 102 and the second electrode 103 are arranged at the corresponding pixel opening 2201. The isolation structure 300 defines a plurality of first openings 301 corresponding to the first sub-pixel 110, the second sub-pixel 120, the third sub-pixel 130, and the fourth sub-pixel 140, and the plurality of pixel openings 2201 are correspondingly in communication with the plurality of first openings 301.

Specifically, the first electrode 101 is an anode and the second electrode 103 is a cathode.

Specifically, the plurality of pixel openings 2201 may be in communication with the plurality of first openings 301 in one-to-one correspondence.

The substrate 210 may be an array substrate including a base, a driver array layer, and a flat layer arranged in a stacked configuration. The base may be a flexible polyimide (PI), a rigid glass, or a thin metal sheet, etc. The embodiments of the present disclosure do not discuss in detail other materials of the base herein, and the person skilled in the art may choose different kinds of materials according to the actual needs.

It is noted that the isolation structure 300 may be provided directly on the substrate 210 or indirectly on the substrate 210. For example, the pixel fixing layer 220 is provided on the substrate 210, and the isolation structure 300 is provided on the pixel fixing layer 220.

In some embodiments, the display panel 10 further includes a plurality of encapsulation units 400 arranged within the plurality of first openings 301 in one-to-one correspondence, and the encapsulation units 400 completely cover the corresponding first sub-pixel 110, the corresponding second sub-pixel 120, the corresponding third sub-pixel 130, or the corresponding fourth sub-pixel 140.

The material of the encapsulation unit 400 may include at least one of an organic material and an inorganic material.

Firstly, the encapsulation unit 400 can prevent water vapor from entering the corresponding first sub-pixel 110, the corresponding second sub-pixel 120, the corresponding third sub-pixel 130, or the corresponding fourth sub-pixel 140, and form respective encapsulations for the corresponding first sub-pixel 110, the corresponding second sub-pixel 120, the corresponding third sub-pixel 130, and the corresponding fourth sub-pixel 140, thereby improving the reliability of the display panel 10. Secondly, the second electrode 103 can contact and thus be electrically connected to the adjacent isolation structure 300, facilitating the provision of required potentials to the second electrodes 103 of the first sub-pixel 110, the second sub-pixel 120, the third sub-pixel 130, and the fourth sub-pixel 140 through the isolation structure 300.

In some embodiments, the display panel 10 further includes an encapsulation layer 500 arranged on the isolation structure 300 and covering the plurality of encapsulation units 400.

The material of the encapsulation layer 500 may include at least one of an organic material and an inorganic material.

The encapsulation layer 500 serves as an overall encapsulation structure for encapsulating all first sub-pixels 110, all second sub-pixels 120, all third sub-pixels 130, all fourth sub-pixels 140, and all encapsulation units 400.

The encapsulation layer 500, in combination with the encapsulation units 400, provides substantially a dual encapsulation effect for the first sub-pixels 110, the second sub-pixels 120, the third sub-pixels 130, and the fourth sub-pixels 140, thereby enhancing the water vapor prevention capability and improving the reliability of the display panel 10.

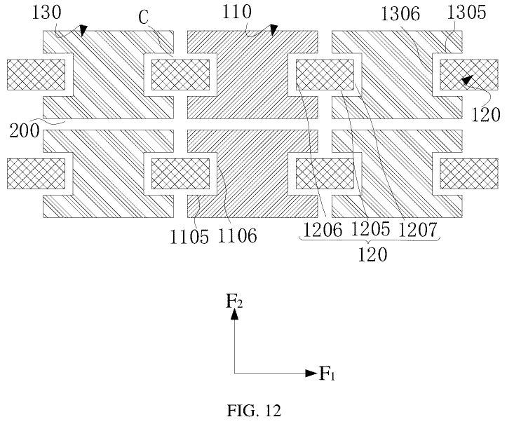

As shown in FIGS. 11 and 12, according to a third aspect of the present disclosure, a pixel arrangement structure is provided. The pixel arrangement structure includes a plurality of sub-pixels, and the plurality of sub-pixels includes first sub-pixels 110, second sub-pixels 120, and third sub-pixels 130 that emit different colors of light. The first sub-pixels 110 and the third sub-pixels 130 are arranged alternately in a first direction F₁, and adjacent first sub-pixel 110 and third sub-pixel 130 are spaced apart by the second sub-pixel 120. In the first direction F₁, the first sub-pixel 110 and the third sub-pixel 130 adjacent to the second sub-pixel 120 each have a portion arranged around the second sub-pixel 120.

As such, the adjacent first sub-pixel 110 and second sub-pixel 120 has a good color mixing effect, and the adjacent second sub-pixel 120 and third sub-pixel 130 have a good color mixing effect, which is conducive to improving the display effect of the display panel 10. Since the adjacent first sub-pixel 110 and the third sub-pixel 130 are spaced apart by a second sub-pixel 120, and the first sub-pixel 110, the second sub-pixel 120 and the third sub-pixel 130 have different light-emitting colors, the pixel unit formed by the first sub-pixel 110, the second sub-pixel 120 and the third sub-pixel 130 has a good color mixing effect. In addition, the first sub-pixel 110, the second sub-pixel 120 and the third sub-pixel 130 in the pixel unit are compactly arranged. As a result, by utilizing the pixel arrangement structure, the aperture ratio of the display panel 10 including the pixel arrangement structure can be improved, and the display effect of the display panel 10 can be improved.

In some embodiments, the light-emitting region of the first sub-pixel 110 includes a third concave portion with an opening facing an adjacent second sub-pixel 120, and the light-emitting region of the third sub-pixel 130 includes a fourth concave portion with an opening facing an adjacent second sub-pixel 120. Adjacent third concave portion and fourth concave portion from adjacent first sub-pixel 110 and third sub-pixel 130 define a third receiving space C for accommodating the second sub-pixel 120 between the adjacent first sub-pixel 110 and third sub-pixel 130.

As such, a portion of the first sub-pixel 110 surrounds the adjacent second sub-pixel 120, and a portion of the third sub-pixel 130 surrounds the adjacent second sub-pixel 120. The color mixing effect of the sequentially adjacent first sub-pixel 110, the second sub-pixel 120, and the third sub-pixel 130 can be improved, and meanwhile, the sequentially adjacent first sub-pixel 110, the second sub-pixel 120, and the third sub-pixel 130 are arranged more closely, which is also conducive to fully utilizing the arrangement space of the display panel 10, and thus conducive to increasing the aperture ratio of the display panel 10.

In some embodiments, the third concave portion includes a fifth boundary 1105 parallel to the first direction F₁, and the fourth concave portion includes a sixth boundary 1305 parallel to the first direction F₁. The light-emitting region of the second sub-pixel 120 includes a fifth pixel edge 1205 adjacent to the fifth boundary 1105 and the sixth boundary 1305. The fifth boundary 1105 and the sixth boundary 1305 are collinear with each other and are each parallel to the fifth pixel edge 1205.

As such, the sixth boundary 1305 can be set to align with the fifth boundary 1105. The spacing between the sixth boundary 1305 and the adjacent fifth pixel edge 1205 is equal to the spacing between the fifth boundary 1105 and the adjacent fifth pixel edge 1205, and the equal spacing is conducive to reducing the difficulty of the production process of the first sub-pixel 110, the second sub-pixel 120 and the third sub-pixel 130 and fully utilizing the arrangement space of the display panel 10, and thus conducive to increasing the aperture ratio of the display panel 10.

In this embodiment, the third concave portion further includes a seventh boundary 1106 parallel to the second direction F₂ intersecting the first direction F₁, and the fourth concave portion further includes an eighth boundary 1306 parallel to the second direction F₂. The light-emitting region of the second sub-pixel 120 further includes a sixth pixel edge 1206 adjacent to and parallel to the seventh boundary 1106. The light-emitting region of the second sub-pixel 120 further includes a seventh pixel edge 1207 adjacent to and parallel to the eighth boundary 1306, but opposite to the sixth pixel edge 1206.

Optionally, the first direction F₁ and the second direction F₂ are perpendicular to each other.

As such, a constant spacing between the sixth pixel edge 1206 and the seventh boundary 1106 can be maintained, which is conducive to reducing the difficulty of the production process of the first sub-pixel 110 and the second sub-pixel 120. A constant space between the seventh pixel edge 1207 and the eighth boundary 1306 can be maintained, which is conducive to reducing the difficulty of the production process of the second sub-pixel 120 and the third sub-pixel 130. It also facilitates full utilization of the arrangement space of the display panel 10, thereby increasing the aperture ratio of the display panel 10.

In this embodiment, the third concave portion includes two fifth boundaries 1105 spaced apart in the second direction F₂, and a seventh boundary 1106 connected between the two fifth boundaries 1105. The light-emitting region of the second sub-pixel 120 includes two fifth pixel edges 1205 spaced apart in the second direction F₂, and a sixth pixel edge 1206 and a seventh pixel edge 1207 connected between the two fifth pixel edges 1205.

As such, the first sub-pixel 110 surrounds the adjacent second sub-pixel 120 more, thereby improving the color mixing effect of the first sub-pixel 110 and the second sub-pixel 120 and also improving the display effect of the display panel 10.

In this embodiment, the fourth concave portion includes two sixth boundaries 1305 spaced apart in the second direction F₂, and an eighth boundary 1306 connected between the two sixth boundaries 1305.

As such, the third sub-pixel 130 surrounds the adjacent second sub-pixel 120 more, thereby improving the color mixing effect of the second sub-pixel 120 and the third sub-pixel 130 and also improving the display effect of the display panel 10.

In some embodiments, referring to FIG. 11, the first sub-pixel 110 and the third sub-pixel 130 are arranged in a column in the second direction F₂ intersecting the first direction F₁.

As a result, it can address the issues such as color fringing, stripe patterns, and jagged edges caused by having the same emitting color for all sub-pixels in a column, and it is beneficial for reducing color fringing, stripe patterns, and jagged edges in display images, thereby improving the display effect of the display panel 10.

In some other embodiments, referring to FIG. 12, the first sub-pixels 110 are arranged in a column in the second direction F₂ intersecting the first direction F₁, and the third sub-pixels 130 are arranged in a column in the second direction F₂. It facilitates the wiring of all the first sub-pixels 110 in the same column and all the third sub-pixels 130 in the same column, and meanwhile, the plurality of sub-pixels can be arranged uniformly, which is to a certain extent conducive to fully utilizing the arrangement space of the display panel 10, and thus conducive to increasing the aperture ratio of the display panel 10.

In some embodiments, in the first direction F₁, a connecting line connecting centers of all the second sub-pixels 120 located in the same row is a straight line. As such, it facilitates the wiring of the second sub-pixels 120 in the same row, and is also beneficial for the second sub-pixels 120 in the same row to be uniformly arranged, which is to a certain extent conducive to fully utilizing the arrangement space of the display panel 10, and thus conducive to increasing the aperture ratio of the display panel 10.

In the second direction F₂ intersecting the first direction F₁, the connecting line connecting centers of all the second sub-pixels 120 located in the same column is a straight line. As such, it facilitates the wiring of the second sub-pixels 120 in the same column, and is also beneficial for the second sub-pixels 120 in the same column to be uniformly arranged, which is to a certain extent conducive to fully utilizing the arrangement space of the display panel 10, and thus conducive to increasing the aperture ratio of the display panel 10.

In some embodiments, the first sub-pixel 110 is symmetrical with respect to a first symmetry line extending in the first direction F₁, and the third sub-pixel 130 is symmetrical with respect to a second symmetry line extending in the first direction F₁. The first sub-pixel 110 is also symmetrical with respect to a third symmetry line extending in the second direction F₂, and the third sub-pixel 130 is also symmetrical with respect to a fourth symmetry line extending in the second direction F₂.

As such, it is conducive to uniformly arranging the first sub-pixels 110 in the same row, uniformly arranging the third sub-pixels 130 in the same row, uniformly arranging the first sub-pixels 110 in the same column, and uniformly arranging the third sub-pixels 130 in the same column, which is to a certain extent conducive to fully utilizing the arrangement space of the display panel 10, and thus conducive to increasing the aperture ratio of the display panel 10.

The first symmetry line of the first sub-pixel 110 and the second symmetry line of the third sub-pixel 130 located in the same row are collinear with each other and pass through the centers of the second sub-pixels 120 in the same row. As such, it is beneficial for the first sub-pixel 110, the second sub-pixels 120, the third sub-pixel 130 and the fourth sub-pixels 140 located in the same row to be uniformly arranged, which is to a certain extent conducive to fully utilizing the arrangement space of the display panel 10, and thus conducive to increasing the aperture ratio of the display panel 10.

In the specific embodiment shown in FIG. 11, the third symmetry line of the first sub-pixel 110 and the fourth symmetry line of the third sub-pixel 130 located in the same column are collinear. As such, the first sub-pixels 110 and the third sub-pixels 130 in the same column can be uniformly arranged, which is to a certain extent conducive to fully utilizing the arrangement space of the display panel 10, and thus conducive to increasing the aperture ratio of the display panel 10.

In the specific embodiment shown in FIG. 12, the fourth symmetry lines of the third sub-pixels 130 in the same column are collinear. As such, the third sub-pixels 130 in the same column can be arranged more uniformly, which is to a certain extent conducive to fully utilizing the arrangement space of the display panel 10, and thus conducive to increasing the aperture ratio of the display panel 10.

In the specific embodiment shown in FIG. 12, the third symmetry lines of the first sub-pixels 110 in the same column are collinear. As such, the first sub-pixels 110 in the same column can be arranged more uniformly, which is to a certain extent conducive to fully utilizing the arrangement space of the display panel 10, and thus conducive to increasing the aperture ratio of the display panel 10.

In some embodiments, the area of the light-emitting region of the first sub-pixel 110 is equal to the area of the light-emitting region of the third sub-pixel 130. As such, the first sub-pixel 110 and the third sub-pixel 130 can be arranged more uniformly, which is conducive to fully utilizing the arrangement space of the display panel 10, and thus conducive to increasing the aperture ratio of the display panel 10.

In some embodiments, the first sub-pixel 110 is one of a blue sub-pixel and a red sub-pixel, the third sub-pixel 130 is the other of the blue sub-pixel and the red sub-pixel, and the second sub-pixel 120 is a green sub-pixel.

The red sub-pixel, the green sub-pixel, and the blue sub-pixel constitute the three primary colors of the color display of the display panel 10, which enables the color display of the display panel 10.

The light-emitting area of the blue sub-pixel is equal to the light-emitting area of the red sub-pixel and is greater than the light-emitting area of the green sub-pixel.

The ratio of the numbers of the first sub-pixel 110, the third sub-pixel 130 and the second sub-pixel 120 is equal to 1:1:2.

Since the second sub-pixel 120 accounts for a larger number of sub-pixels, the second sub-pixel 120 may be set to be a sub-pixel of a color sensitive to the human eye, such as a green sub-pixel, which is conducive to improving the resolution of the display panel 10 while making the display of the display panel 10 more uniform.

In some embodiments, connecting lines that connect centers of four adjacent second sub-pixels 120 in two adjacent rows form a quadrilateral, and the quadrilateral may be a rectangle. Further, the quadrilateral may be a square.

The four adjacent second sub-pixels 120 in the two adjacent rows can be arranged more uniformly, which is to a certain extent conducive to fully utilizing the arrangement space of the display panel 10, and thus conducive to increasing the aperture ratio of the display panel 10.

According to a fourth aspect of the present disclosure, a display panel 10 is provided, which includes the pixel arrangement structure of any of the above embodiments.

Referring to FIG. 10, the display panel 10 further includes a substrate 210 and an isolation structure 300. The plurality of sub-pixels and the isolation structure 300 are arranged on the substrate 210. The isolation structure 300 is configured to space apart adjacent sub-pixels.

The isolation structure 300 is configured to space apart the pixel materials of two adjacent ones of the first sub-pixel 110, the second sub-pixel 120 and the third sub-pixel 130, so that during the process of forming the plurality of repetitive units 100 by evaporation, the need for expensive fine metal mask (FMM) can be eliminated. As a result, the structural design of the first sub-pixel 110, the second sub-pixel 120, and the third sub-pixel 130 are no longer limited by the fine metal mask (FMM). Thus, the isolation structure 300, the first sub-pixel 110, the second sub-pixel 120, and the third sub-pixel 130 may be designed in accordance with the need for increasing the aperture ratio of the display panel 10, which is conducive to increasing the aperture ratio of the display panel 10 and improving the display effect of the display panel 10, while decreasing the cost of production of the display panel 10.

The specific structures of the isolation structure 300 and the like can be set with reference to the specific structure of the display panel 10 in the second aspect as described above, and will not be elaborated here.

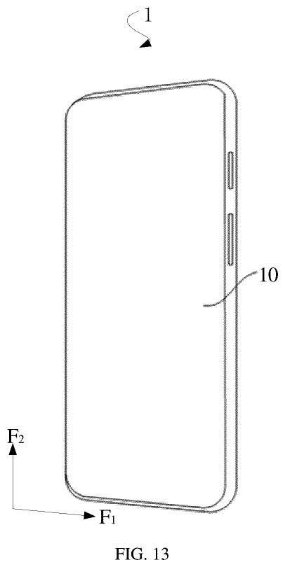

Referring to FIG. 13, according to a fifth aspect of the present disclosure, a display device 1 is provided, which includes a display panel 10 as described above.

The display device 1 may be a mobile or fixed terminal with a display panel 10, such as a cell phone, a television, a tablet computer, a laptop computer, an ultra-mobile personal computer (UMPC), a personal digital assistant (PDA), a navigation device, a smart watch, or a virtual reality device.

The display device 1 provided by the embodiments of the present disclosure can increase the aperture ratio of the display panel 10 and improve the display effect of the display panel 10.

The technical features of the embodiments described above can be combined arbitrarily. In order to keep the description concise, not all possible combinations of technical features in the embodiments above have been described. However, as long as there is no contradiction in the combination of these technical features, it should be considered within the scope of the present specification.

The embodiments described above only express several embodiments of the present disclosure, with detailed and specific descriptions, but this should not be construed as limiting the scope of the patent application. It should be noted that ordinary skilled persons in this field can make various modifications and improvements without departing from the concept of the present disclosure, and these are all within the scope of protection of the present disclosure. Therefore, the scope of protection of the patent application shall be subject to the appended claims.

What is claimed is:

1. A pixel arrangement structure, comprising a plurality of repeating units, each repeating unit comprising:
a first sub-pixel group comprising a first sub-pixel and a second sub-pixel, and a light-emitting region of the first sub-pixel partially surrounding a light-emitting region of the second sub-pixel; and
a second sub-pixel group comprising a third sub-pixel and a fourth sub-pixel, and a light-emitting region of the third sub-pixel partially surrounds a light-emitting region of the fourth sub-pixel;
wherein a light-emitting color of the second sub-pixel is the same as a light-emitting color of the fourth sub-pixel, and is different from a light-emitting color of the first sub-pixel and a light-emitting color of the third sub-pixel; and
the second sub-pixel and the fourth sub-pixel which are adjacent to each other are spaced apart by the first sub-pixel or the third sub-pixel.

2. The pixel arrangement structure according to claim 1, wherein the plurality of repeating units is disposed in an array in a first direction and a second direction intersecting the first direction, the repeating units adjacent to each other in two adjacent rows are arranged in a staggered manner;
in one of the repeating units, the first sub-pixel group is adjacent to the second sub-pixel group in the first direction;
in two adjacent repeating units in the first direction, the first sub-pixel group of one of the two adjacent repeating units is adjacent to the second sub-pixel group of the other of the two adjacent repeating units; and
in two adjacent repeating units in the second direction, the first sub-pixel group of one of the two adjacent repeating units and the second sub-pixel group of the other of the two adjacent repeating units are in the same column.

3. The pixel arrangement structure according to claim 1, wherein a connecting line connecting centers of the second sub-pixels and the fourth sub-pixels located in the same row in a first direction is a straight line;
a connecting line connecting centers of the second sub-pixels and the fourth sub-pixels located in the same column in a second direction intersecting the first direction is a straight line or a broken line;
the first sub-pixel is axially symmetrical with respect to a first symmetry line extending in the first direction, and the third sub-pixel is axially symmetrical with respect to a second symmetry line extending in the first direction;
the first symmetry line of the first sub-pixel and the second symmetry line of the third sub-pixel located in the same row are collinear with each other, and pass through the centers of the second sub-pixels and the fourth sub-pixels located in the same row.

4. The pixel arrangement structure according to claim 1, wherein the plurality of repeating units is disposed in an array in a first direction and a second direction intersecting the first direction;
in two adjacent repeating units in the second direction, the first sub-pixel group of one of the two adjacent repeating units and the first sub-pixel group of the other of the two adjacent repeating units are in the same column;
the second sub-pixel group of one of two adjacent repeating units in the second direction and the second sub-pixel group of the other of the two adjacent repeating units are in the same column;
the first sub-pixel group and the second sub-pixel group of the repeating unit are adjacently arranged in the first direction; and
the first sub-pixel group of one of two adjacent repeating units in the first direction and the second sub-pixel group of the other of the two adjacent repeating units are adjacent to each other.

5. The pixel arrangement structure according to claim 1, wherein a connecting line connecting centers of the second sub-pixels and the fourth sub-pixels located in the same row in a first direction is a straight line;
a connecting line connecting centers of the second sub-pixels and the fourth sub-pixels located in the same column in a second direction intersecting the first direction is a straight line;
the first sub-pixel is axially symmetrical with respect to a first symmetry line extending in the first direction, and the third sub-pixel is axially symmetrical with respect to a second symmetry line extending in the first direction; and
the first symmetry line of the first sub-pixel and the second symmetry line of the third sub-pixel located in the same row are collinear with each other, and pass through the centers of the second sub-pixels and the fourth sub-pixels located in the same row.

6. The pixel arrangement structure according to claim 1, wherein the light-emitting region of the first sub-pixel comprises a first concave portion with an opening facing the second sub-pixel adjacent to the first sub-pixel,
the light-emitting region of the second sub-pixel adjacent to the first sub-pixel is at least partially received in a first receiving space enclosed by the first concave portion;
the first concave portion comprises a first boundary parallel to a first direction and a second boundary parallel to a second direction intersecting the first direction, wherein the first boundary is connected to the second boundary, the light-emitting region of the second sub-pixel comprises a first pixel edge adjacent to and parallel to the first boundary, or, the light-emitting region of the second sub-pixel comprises a second pixel edge adjacent to and parallel to the second boundary; or
the first concave portion comprises two first boundaries spaced apart in the second direction and the second boundary connected between the two first boundaries, the light-emitting region of the second sub-pixel comprises two first pixel edges spaced apart in the second direction and the second pixel edge connected between the two first pixel edges.

7. The pixel arrangement structure according to claim 1, wherein the light-emitting region of the third sub-pixel comprises a second concave portion with an opening facing the fourth sub-pixel adjacent to the third sub-pixel,
the light-emitting region of the fourth sub-pixel adjacent to the third sub-pixel is at least partially received in a second receiving space enclosed by the second concave portion;
the second concave portion comprises a third boundary parallel to a first direction and a fourth boundary parallel to a second direction intersecting the first direction, wherein the third boundary is connected to the fourth boundary, the light-emitting region of the fourth sub-pixel comprises a third pixel edge adjacent to and parallel to the third boundary, and/or, the light-emitting region of the fourth sub-pixel comprises a fourth pixel edge adjacent to and parallel to the fourth boundary; or
the second concave portion comprises two third boundaries spaced apart in the second direction and the fourth boundary connected between the two third boundaries, and the light-emitting region of the fourth sub-pixel comprises two third pixel edges spaced apart in the second direction and the fourth pixel edge connected between the two third pixel edges.

8. The pixel arrangement structure according to claim 1, wherein the light-emitting region of the first sub-pixel comprises a first concave portion with an opening facing the second sub-pixel adjacent to the first sub-pixel, the light-emitting region of the third sub-pixel comprises a second concave portion with an opening facing the fourth sub-pixel adjacent to the third sub-pixel;
the light-emitting region of the second sub-pixel adjacent to the first sub-pixel is at least partially received in a first receiving space enclosed by the first concave portion; and
the light-emitting region of the fourth sub-pixel adjacent to the third sub-pixel is at least partially received in a second receiving space enclosed by the second concave portion.

9. The pixel arrangement structure according to claim 1, wherein an area of the light-emitting region of the first sub-pixel is greater than or equal to an area of the light-emitting region of the third sub-pixel; or
an area of the light-emitting region of the second sub-pixel is equal to an area of the light-emitting region of the fourth sub-pixel;
the area of the light-emitting region of the first sub-pixel is greater than the area of the light-emitting region of the third sub-pixel;
the light-emitting region of the first sub-pixel comprises a first sub-light-emitting region extending in a first direction and a second sub-light-emitting region extending in a second direction intersecting the first direction;
the light-emitting region of the third sub-pixel comprises a third sub-light-emitting region extending in the first direction and a fourth sub-light-emitting region extending in the second direction;
a size of the first sub-light-emitting region in the second direction is equal to a size of the third sub-light-emitting region in the second direction; and
a size of the second sub-light-emitting region in the first direction is greater than a size of the fourth sub-light-emitting region in the first direction.

10. The pixel arrangement structure according to claim 1, wherein connecting lines connecting centers of two second sub-pixels and centers of two fourth sub-pixels from four adjacent sub-pixel groups in two adjacent rows form a quadrilateral;
the quadrilateral comprises a first side and a second side opposite to each other in a second direction, and a third side and a fourth side opposite to each other in a first direction intersecting the second direction;
at least one of the first side and the second side is parallel to the first direction;
a length of the first side is equal or unequal to a length of the second side, or a length of the third side is equal to a length of the fourth side;
the quadrilateral is a trapezoid or a square.

11. The pixel arrangement structure according to claim 1, wherein the second sub-pixel and the fourth sub-pixel are green sub-pixels, a light-emitting color of the first sub-pixel is different from a light-emitting color of the third sub-pixel;
the first sub-pixel is one of a blue sub-pixel and a red sub-pixel, and the third sub-pixel is the other of the blue sub-pixel and the red sub-pixel; and
a light-emitting area of the blue sub-pixel is greater than a light-emitting area of the red sub-pixel and greater than a light-emitting area of the green sub-pixel.

12. A pixel arrangement structure, comprising a plurality of sub-pixels, wherein the plurality of sub-pixels comprises first sub-pixels, second sub-pixels and third sub-pixels that emit light of different colors,
the first sub-pixels and the third sub-pixels are arranged alternately in a first direction, and a first sub-pixel and a third sub-pixel adjacent to each other are spaced apart by one second sub-pixel, and
the first sub-pixel and the third sub-pixel adjacent to the second sub-pixel in the first direction each have a portion arranged around the second sub-pixel.

13. The pixel arrangement structure according to claim 12, wherein a light-emitting region of the first sub-pixel comprises a third concave portion with an opening facing the second sub-pixel adjacent to the first sub-pixel, and a light-emitting region of the third sub-pixel comprises a fourth concave portion with an opening facing the second sub-pixel adjacent to the third sub-pixel; and
adjacent third concave portion and fourth concave portion of adjacent first and third sub-pixels define a third receiving space configured to receive the second sub-pixel between the adjacent first and third sub-pixels.

14. The pixel arrangement structure according to claim 13, wherein the third concave portion comprises a fifth boundary parallel to the first direction,
the fourth concave portion comprises a sixth boundary parallel to the first direction, and a light-emitting region of the second sub-pixel comprises a fifth pixel edge adjacent to the fifth boundary and the sixth boundary, and the fifth boundary and the sixth boundary are collinear with each other and are parallel to the fifth pixel edge.

15. The pixel arrangement structure according to claim 14, wherein the third concave portion further comprises a seventh boundary parallel to a second direction intersecting the first direction, and the fourth concave portion further comprises an eighth boundary parallel to the second direction,
the light-emitting region of the second sub-pixel further comprises a sixth pixel edge adjacent to and parallel to the seventh boundary, and
the light-emitting region of the second sub-pixel further comprises a seventh pixel edge which is adjacent to and parallel to the eighth boundary, but opposite to the sixth pixel edge.

16. The pixel arrangement structure according to claim 15, wherein the third concave portion comprises two fifth boundaries spaced apart in the second direction and the seventh boundary connected between the two fifth boundaries,
the light-emitting region of the second sub-pixel comprises two fifth pixel edges spaced apart in the second direction, and the sixth pixel edge and the seventh pixel edge connected between the two fifth pixel edges; and
the fourth concave portion comprises two sixth boundaries spaced apart in the second direction, and the eighth boundary connected between the two sixth boundaries.

17. The pixel arrangement structure according to claim 12, wherein the first sub-pixels are arranged in a column in a second direction intersecting the first direction, and the third sub-pixels are arranged in a column in the second direction; or
the first sub-pixels and the third sub-pixels are arranged in a column in the second direction.

18. The pixel arrangement structure according to claim 12, wherein a connecting line connecting centers of all the second sub-pixels located in the same row in the first direction is a straight line;
a connecting line connecting centers of all the second sub-pixels located in the same column in a second direction intersecting the first direction is a straight line;
the first sub-pixel is axially symmetrical with respect to a first symmetry line extending in the first direction, and the third sub-pixel is axially symmetrical with respect to a second symmetry line extending in the first direction;
the first symmetry line of the first sub-pixel and the second symmetry line of the third sub-pixel located in the same row are collinear with each other, and pass through the centers of the second sub-pixels located in the same row;
the first sub-pixel is axially symmetrical with respect to a third symmetry line extending in the second direction, and the third sub-pixel is axially symmetrical with respect to a fourth symmetry line extending in the second direction; and
third symmetry lines of the first sub-pixels located in the same column are collinear, the fourth symmetry lines of the third sub-pixels located in the same column are collinear, or the third symmetry line of the first sub-pixel and the fourth symmetry line of the third sub-pixel that are located in the same column are collinear.

19. The pixel arrangement structure according to claim 12, wherein a ratio of numbers of the first sub-pixels, the third sub-pixels and the second sub-pixels is equal to 1:1:2.

20. A display panel, comprising:
a substrate;
a pixel arrangement structure according to claim 1, the plurality of the sub-pixels provided on the substrate; and
an isolation structure provided on the substrate and disposed to space apart adjacent repeating units and space apart every two adjacent sub-pixels of the first sub-pixel, the second sub-pixel, the third sub-pixel and the fourth sub-pixel in the same repeating unit.

21. The display panel according to claim 20, wherein
an outer contour of an orthogonal projection of a top surface of the isolation structure onto the substrate is outside an outer contour of an orthogonal projection of a bottom surface of the isolation structure onto the substrate; and
the isolation structure comprising a first isolation portion and a second isolation portion stacked on the substrate, an outer contour of an orthogonal projection of the second isolation portion onto the substrate being outside an outer contour of an orthogonal projection of the corresponding first isolation portion onto the substrate, and a width of a bottom surface of the second isolation portion being greater than a width of a top surface of the first isolation portion.

22. A display panel, comprising:
a substrate;
a pixel arrangement structure according to claim 12, the plurality of the sub-pixels provided on the substrate; and
an isolation structure provided on the substrate and disposed to space apart adjacent sub-pixels.

23. The display panel according to claim 22, wherein
an outer contour of an orthogonal projection of a top surface of the isolation structure onto the substrate is outside an outer contour of an orthogonal projection of a bottom surface of the isolation structure onto the substrate; and
the isolation structure comprising a first isolation portion and a second isolation portion stacked on the substrate, an outer contour of an orthogonal projection of the second isolation portion onto the substrate being outside an outer contour of an orthogonal projection of the corresponding first isolation portion onto the substrate, and a width of a bottom surface of the second isolation portion being greater than a width of a top surface of the first isolation portion.
